(19) United States
(12) Patent Application Publication
(10) Pub. No.: US 2026/0296012 A1
(43) Pub. Date: Oct. 1, 2026

(54) PIEZOELECTRIC DEVICE AND LIQUID DISCHARGE HEAD

(71) Applicant: SEIKO EPSON CORPORATION, Tokyo (JP)

(72) Inventors: Shiro YAZAKI, CHINO-SHI (JP); Misaki ADACHI, MATSUMOTO-SHI (JP); Takatoshi YAMAZAKI, SHIOJIRI-SHI (JP)

(21) Appl. No.: 19/577,785

(22) Filed: Mar. 25, 2026

(30) Foreign Application Priority Data
Mar. 27, 2025 (JP) 2025-053128

(51) Int. Cl. B41J 2/14; H10N 30/20; H10N 30/853

(52) U.S. Cl. CPC B41J 2/14233; H10N 30/2047; H10N 30/8554; B41J 2002/14258

(57) ABSTRACT

A piezoelectric device includes a diaphragm coupled to a pressure chamber substrate to partition part of a pressure chamber, and a piezoelectric element in which a lower electrode, a piezoelectric layer, and an upper electrode are stacked on the diaphragm along a stacking direction on a side opposite to the pressure chamber. The diaphragm vibrates in response to driving of the piezoelectric element. When a region where the pressure chamber and the diaphragm overlap in the stacking direction is defined as a flexible region in a width direction intersecting the stacking direction, the flexible region includes an active region where the diaphragm and the electrodes and piezoelectric layer overlap. An inflection point of the diaphragm deflection when the piezoelectric element is not driven is located in the flexible region outside the active region.

The present application is based on, and claims priority from JP Application Serial Number 2025-053128, filed Mar. 27, 2025, the disclosure of which is hereby incorporated by reference herein in its entirety.

### BACKGROUND

### 1. Technical Field

The present disclosure relates to a piezoelectric device and a liquid discharge head.

### 2. Related Art

A liquid discharge apparatus that discharges a liquid by driving a piezoelectric device included in a liquid discharge head is known. For example, JP-A-2004-42329 discloses a liquid discharge head including a substrate in which a pressure chamber is formed, a diaphragm formed at the substrate, and a piezoelectric thin film element formed at the diaphragm, in which the diaphragm is deflected so as to be convex toward the pressure chamber side, and a deflection amount of the diaphragm is 0.4% or less of a width of the pressure chamber.

Meanwhile, a piezoelectric device is required to be further improved. For example, it is required to suppress a decrease in displacement efficiency of a piezoelectric layer included in the piezoelectric device.

### SUMMARY

In order to solve the above problems, according to an aspect of the present disclosure, there is provided a piezoelectric device including: a diaphragm that is coupled to a first substrate and partitions a part of a space together with the first substrate; and a piezoelectric element in which a lower electrode, a piezoelectric layer, and an upper electrode are stacked in this order along a stacking direction on a side opposite to the space of the diaphragm, in which the diaphragm vibrates in response to driving of the piezoelectric element, when a region in which the space and the diaphragm overlap when viewed in the stacking direction is defined as a flexible region in a width direction intersecting the stacking direction, the flexible region includes an active region in which the diaphragm, the lower electrode, the piezoelectric layer, and the upper electrode overlap when viewed in the stacking direction, and an inflection point of deflection of the diaphragm in a state in which the piezoelectric element is not driven is located in a portion of the flexible region other than the active region in the width direction.

In addition, according to another aspect of the present disclosure, there is provided a liquid discharge head including the above-described piezoelectric device, in which a liquid is discharged by driving the piezoelectric device.

According to still another aspect of the present disclosure, there is provided a piezoelectric device including: a diaphragm that is coupled to a first substrate and partitions a part of a space together with the first substrate; and a piezoelectric element in which a lower electrode, a piezoelectric layer, and an upper electrode are stacked in this order along a stacking direction on a side opposite to the space of the diaphragm, in which the diaphragm vibrates in response to driving of the piezoelectric element, when a region in which the space and the diaphragm overlap when viewed in the stacking direction is defined as a flexible region in a width direction intersecting the stacking direction, the flexible region includes an active region in which the diaphragm, the lower electrode, the piezoelectric layer, and the upper electrode overlap when viewed in the stacking direction, and an inflection point of deflection of the diaphragm in a state of being most deflected toward the space when the piezoelectric element is driven is located in a portion of the flexible region other than the active region in the width direction.

### BRIEF DESCRIPTION OF THE DRAWINGS

FIG. 1 is an explanatory diagram for describing an example of a liquid discharge apparatus including a liquid discharge head according to an embodiment of the present disclosure.

FIG. 2 is an explanatory diagram for explaining a schematic structure of the liquid discharge head.

FIG. 3 is an explanatory diagram for explaining a schematic structure of a piezoelectric device.

FIG. 4 is an explanatory diagram for explaining deflection of a diaphragm.

FIG. 5 is a diagram illustrating a simulation result of the deflection of the diaphragm.

FIG. 6 is a cross-sectional view of a piezoelectric device according to a first modification example.

FIG. 7 is a cross-sectional view of another example of the piezoelectric device according to the first modification example.

### DESCRIPTION OF EMBODIMENTS

Hereinafter, embodiments for carrying out the present disclosure will be described with reference to the drawings. However, in each drawing, the dimensions and scales of each part are appropriately different from those of the actual ones. The embodiments described below are preferred specific examples of the present disclosure and are thus provided with various technically preferred limitations, but the scope of the present disclosure is not limited to such embodiments unless description for limiting the present disclosure is made in the following description.

### 1. Embodiment

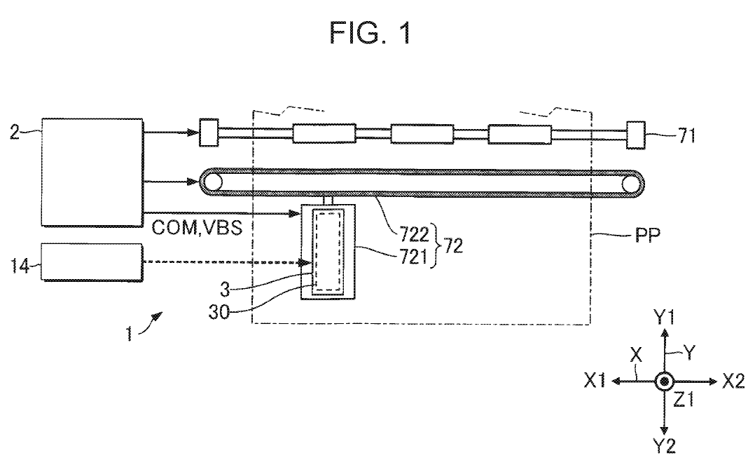

First, an outline of a liquid discharge apparatus 1 according to the present embodiment will be described with reference to FIG. 1. In the present embodiment, a case where the liquid discharge apparatus 1 is a serial printer will be assumed as an example.

FIG. 1 is an explanatory diagram for describing an example of a liquid discharge apparatus 1 including a liquid discharge head 3 according to an embodiment of the present disclosure. For convenience of description, the following description will be made using an X axis, a Y axis, and a Z axis, which are orthogonal to each other as appropriate. In the following description, one direction along the X axis is referred to as an X1 direction, and the direction opposite to the X1 direction is referred to as an X2 direction. Similarly, one direction along the Y axis is referred to as a Y1 direction, and the direction opposite to the Y1 direction is referred to as a Y2 direction. One direction along the Z axis is referred to as a Z1 direction, and the direction opposite to the Z1 direction is referred to as a Z2 direction. In addition, in the following, viewing from the Z1 direction or the Z2 direction may be referred to as a "plan view".

The liquid discharge apparatus 1 of FIG. 1 is an ink jet type printing apparatus that discharges ink to a medium PP. The ink is an example of a "liquid". The medium PP is typically printing paper, but any printing target made of a resin film, fabric, or other material may be used as the medium PP.

As illustrated in FIG. 1, the liquid discharge apparatus 1 is equipped with a liquid container 14 for storing the ink. As the liquid container 14, for example, a cartridge that can be attached to and detached from the liquid discharge apparatus 1, a bag-shaped ink pack formed of a flexible film, an ink tank that can be replenished with ink, or the like can be employed. A type of ink to be stored in the liquid container 14 is not particularly limited, and is selected in any desired way.

Further, the liquid discharge apparatus 1 includes a control unit 2, a medium transport mechanism 71, a carriage transport mechanism 72, and a liquid discharge head 3. The control unit 2 includes, for example, one or a plurality of processing circuits such as a central processing unit (CPU) or a field programmable gate array (FPGA), and one or a plurality of storage circuits such as a semiconductor memory, and controls each element of the liquid discharge apparatus 1 in an integrated manner. For example, the control unit 2 supplies the liquid discharge head 3 with a drive signal COM for driving the piezoelectric device 30 included in the liquid discharge head 3, a reference potential VBS, and the like.

The medium transport mechanism 71 transports the medium PP in the Y2 direction along the Y axis under the control of the control unit 2. Further, the carriage transport mechanism 72 reciprocates the liquid discharge head 3 along the X axis under the control of the control unit 2. The carriage transport mechanism 72 includes, for example, a substantially box-shaped carriage 721 that accommodates the liquid discharge head 3, and an endless belt 722 to which the carriage 721 is fixed. A configuration in which a plurality of liquid discharge heads 3 are mounted on the carriage 721 may be adopted. Further, the liquid container 14 may be accommodated in the carriage 721 together with the liquid discharge head 3.

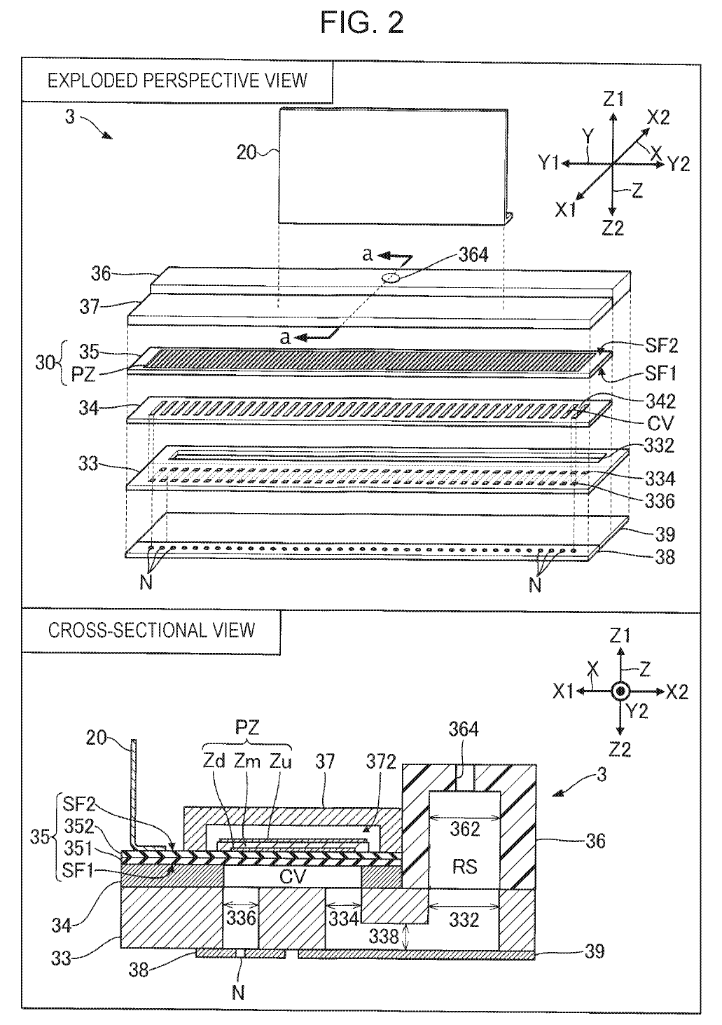

The liquid discharge head 3 discharges ink to the medium PP by driving the piezoelectric device 30 under the control of the control unit 2. For example, the liquid discharge head 3 drives the piezoelectric device 30 to discharge the ink supplied from the liquid container 14 to the medium PP from a plurality of nozzles N illustrated in FIG. 2 and the like to be described later. An image is formed at the surface of the medium PP by discharging the ink to the medium PP by each liquid discharge head 3 in parallel with the transport of the medium PP by the medium transport mechanism 71 and the repetitive reciprocation of the carriage 721.

Next, a schematic structure of the liquid discharge head 3 will be described with reference to FIG. 2.

FIG. 2 is an explanatory diagram for explaining a schematic structure of the liquid discharge head 3. An upper part of FIG. 2 is an exploded perspective view of the liquid discharge head 3, and a lower part of FIG. 2 is a cross-sectional view taken along line a-a illustrated in the exploded perspective view. The a-a cross section is parallel to the XZ plane, and passes through an introduction port 364 described below.

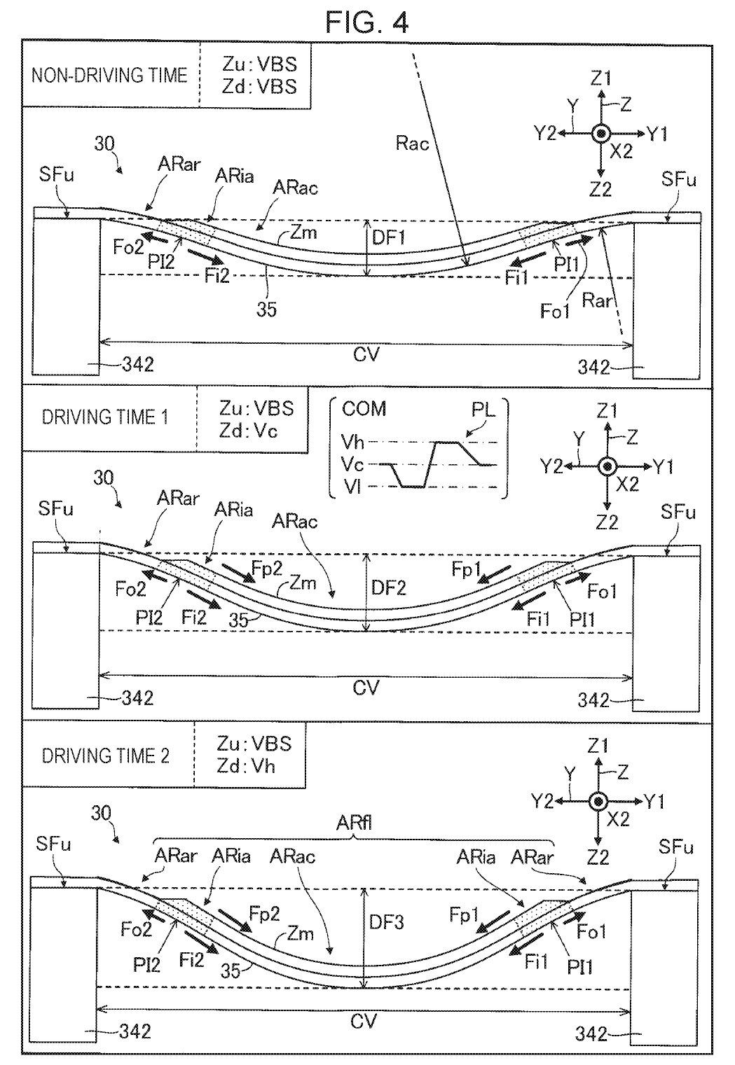

As illustrated in FIG. 2, the liquid discharge head 3 includes a piezoelectric device 30 including a diaphragm 35 and a plurality of piezoelectric elements PZ, a flow path substrate 33, a pressure chamber substrate 34, a case 36, a sealing plate 37, a nozzle substrate 38, and a vibration absorber 39. Further, the liquid discharge head 3 includes a wiring substrate 20 which is a mounting component on which a plurality of wirings for electrically coupling the control unit 2 and the piezoelectric element PZ are formed. For example, a flexible wiring substrate 20 such as a flexible printed circuit (FPC) or a flexible flat cable (FFC) is suitably adopted. The drive signal COM and the reference potential VBS for driving the piezoelectric element PZ are supplied from the wiring substrate 20 to each piezoelectric element PZ. The drive signal COM includes, for example, a discharge pulse PL for discharging ink, as illustrated in FIG. 4 described later. In addition, the reference potential VBS may be a ground potential or may be a potential different from the ground potential.

Here, the pressure chamber substrate 34, the diaphragm 35, the plurality of piezoelectric elements PZ, the case 36, and the sealing plate 37 are installed in a region located in the Z1 direction from the flow path substrate 33. Meanwhile, the nozzle substrate 38 and the vibration absorber 39 are installed in a region located in the Z2 direction from the flow path substrate 33. Further, the wiring substrate 20 is provided on, for example, a surface of the sealing plate 37 in the Z1 direction. Each element of the liquid discharge head 3 is generally a plate-shaped member elongated in the direction along the Y axis, and is bonded to each other with an adhesive, for example.

As illustrated in the exploded perspective view of FIG. 2, the nozzle substrate 38 is a plate-shaped member in which a plurality of nozzles N arranged along the Y axis are formed. Each of the nozzles N is a through-hole through which ink passes. The flow path substrate 33, the pressure chamber substrate 34, and the nozzle substrate 38 are formed by processing, for example, a silicon single crystal substrate by a semiconductor manufacturing technology such as etching. However, the material and the manufacturing method of each element of the liquid discharge head 3 are optional.

The flow path substrate 33 is a plate-shaped member for forming a flow path for inks. As illustrated in FIG. 2, the flow path substrate 33 is formed with an opening section 332, a plurality of supply flow paths 334, and a plurality of communication flow paths 336. The opening section 332 is a through-hole that is continuous over the plurality of nozzles N along the Y axis in plan view. That is, the opening section 332 is a long through-hole extending in the direction along the Y axis. The supply flow path 334 and the communication flow path 336 are through-holes individually formed for each of the nozzles N. As illustrated in the cross-sectional view in FIG. 2, a relay flow path 338 over the plurality of supply flow paths 334 is formed at a surface of the flow path substrate 33 in the Z2 direction. The relay flow path 338 is a flow path that allows the opening section 332 and the plurality of supply flow paths 334 to communicate with each other.

The pressure chamber substrate 34 is a plate-shaped member in which a plurality of pressure chambers CV corresponding to the plurality of nozzles N are formed. The pressure chamber CV is a space called a cavity for applying pressure to the ink filling the pressure chamber CV. For example, the pressure chamber CV is a space located between the flow path substrate 33 and the diaphragm 35 and partitioned by a partition wall 342 of the pressure chamber substrate 34. The plurality of pressure chambers CV are arranged in the direction along the Y axis. Each pressure chamber CV is configured with a hole that opens at both surfaces of the pressure chamber substrate 34, and has a long shape extending in the direction along the X axis. That is, the direction along the X axis corresponds to the longitudinal direction of the pressure chamber CV. An end of each pressure chamber CV in the X2 direction communicates with the corresponding supply flow path 334 among the plurality of supply flow paths 334. Meanwhile, an end of each pressure chamber CV in the X1 direction communicates with the corresponding communication flow path 336 among the plurality of communication flow paths 336.

The diaphragm 35 is installed on a surface of the pressure chamber substrate 34 in a direction opposite to a surface facing the flow path substrate 33. The diaphragm 35 is a plate-shaped member that is elastically deformable. As illustrated in the cross-sectional view of FIG. 2, the diaphragm 35 includes an insulating film 352 and an elastic film 351 stacked in the direction along the Z axis. In the present specification, the expression "the element A and the element B are stacked" is not intended to limit the configuration to the element A and the element B being in direct contact with each other. In other words, a configuration in which another element C is interposed between the element A and the element B is also included in the concept of "elements A and B are stacked". Likewise, the expression "the element B is formed at the surface of the element A" is not limited to a configuration in which the element A and the element B come into direct contact with each other. That is, a configuration where an element C is formed at the surface of the element A and the element B is formed at a surface of the element C is also included in the concept "the element B is formed at the surface of the element A" insofar as at least a part of the element A and a part of the element B overlap in plan view. The insulating film 352 is located in a direction opposite to the pressure chamber substrate 34 when viewed from the elastic film 351. The elastic film 351 is formed of, for example, silicon oxide. The insulating film 352 is formed of, for example, zirconium oxide.

As can be understood from FIG. 2, the flow path substrate 33 and the diaphragm 35 face each other at an interval inside each of the pressure chambers CV. The diaphragm 35 forms a part of a wall surface of the pressure chamber CV. For example, the diaphragm 35 has a first surface SF1 and a second surface SF2 opposite to the first surface SF1. The pressure chamber substrate 34 is provided on the first surface SF1 side of the diaphragm 35. In this case, the first surface SF1 of the diaphragm 35 constitutes a part of the wall surface of the pressure chamber CV. As described above, the diaphragm 35 is coupled to the pressure chamber substrate 34 and partitions a portion of the pressure chamber CV together with the pressure chamber substrate 34. The pressure chamber substrate 34 is an example of a "first substrate", and the pressure chamber CV is an example of a "space". As illustrated in the cross-sectional view of FIG. 2, the ink stored in a liquid storage chamber RS is branched from the relay flow path 338 to the respective supply flow paths 334 and is supplied in parallel to the plurality of pressure chambers CV to fill the pressure chambers CV.

As illustrated in FIG. 2, the plurality of piezoelectric elements PZ corresponding to the plurality of nozzles N are provided on the surface of the diaphragm 35 in the direction opposite to the pressure chamber substrate 34, that is, the second surface SF2. The nozzles N corresponding to the piezoelectric elements PZ are nozzles N that communicate with the pressure chambers CV of which some or all overlap the piezoelectric element PZ in plan view. Each of the piezoelectric elements PZ is an actuator that is deformed by the supply of the drive signal COM, and is formed in a long shape in a direction along the X axis. The plurality of piezoelectric elements PZ are arranged in the direction along the Y axis to correspond to the plurality of pressure chambers CV. When the drive signal COM is supplied to the piezoelectric element PZ and the diaphragm 35 vibrates in conjunction with deformation of the piezoelectric element PZ, pressure in the pressure chamber CV fluctuates. As the pressure in the pressure chamber CV fluctuates, the ink filled in the pressure chamber CV passes through the communication flow path 336 and the nozzle N, and is discharged. That is, the piezoelectric element PZ is a drive element that discharges the ink in the pressure chamber CV from the nozzle N by vibrating the diaphragm 35. As described above, the diaphragm 35 vibrates in response to the drive of the piezoelectric element PZ.

As illustrated in the cross-sectional view of FIG. 2, the piezoelectric element PZ includes a lower electrode Zd to which the drive signal COM is supplied, an upper electrode Zu to which the reference potential VBS is supplied, and a piezoelectric layer Zm provided between the lower electrode Zd and the upper electrode Zu. For example, the lower electrode Zd, the piezoelectric layer Zm, and the upper electrode Zu are stacked in this order along the Z1 direction from the first surface SF1 to the second surface SF2 on the second surface SF2 side of the diaphragm 35. The pressure chamber CV is provided in the Z2 direction of the piezoelectric element PZ. The direction along the Z axis, that is, the Z1 direction and the Z2 direction are examples of a "stacking direction". In addition, the direction along the Y axis corresponds to the direction intersecting the direction along the Z axis, and is an example of the "width direction".

In FIG. 2, in order to avoid the drawing from being complicated, a wiring which is coupled to the lower electrode Zd and supplies the drive signal COM to the lower electrode Zd and a wiring which is coupled to the upper electrode Zu and supplies the reference potential VBS to the upper electrode Zu are not illustrated.

As illustrated in FIG. 2, the case 36 is, for example, a structure manufactured by injection molding of a resin material, and is fixed to a surface of the flow path substrate 33 in the Z1 direction. As illustrated in the cross-sectional view of FIG. 2, the case 36 is formed with an accommodation section 362 and the introduction port 364. The accommodation section 362 is a recessed section having an outer shape corresponding to the opening section 332 of the flow path substrate 33. The introduction port 364 is a through-hole that communicates with the accommodation section 362. A space formed by the opening section 332 of the flow path substrate 33 and the accommodation section 362 of the case 36 functions as the liquid storage chamber RS which is a reservoir that stores inks to be supplied to the plurality of pressure chambers CV. The ink supplied from the liquid container 14 and passing through the introduction port 364 is stored in the liquid storage chamber RS.

The sealing plate 37 has a structure that protects the plurality of piezoelectric elements PZ from the outside air and reinforces the mechanical strength of the pressure chamber substrate 34 and the diaphragm 35. The sealing plate 37 is fixed to the second surface SF2 of the diaphragm 35 with, for example, an adhesive. As illustrated in the cross-sectional view of FIG. 2, the sealing plate 37 has a recessed section on a surface facing the diaphragm 35. A sealing space 372 is formed by fixing the sealing plate 37 to the second surface SF2 of the diaphragm 35. The plurality of piezoelectric elements PZ are contained in the sealing space 372.

The vibration absorber 39 absorbs the pressure fluctuation in the liquid storage chamber RS. That is, the vibration absorber 39 absorbs the vibration of the inks stored in the liquid storage chamber RS. For example, the vibration absorber 39 includes a flexible sheet member that can be elastically deformed. Specifically, the vibration absorber 39 is installed on a surface of the flow path substrate 33 in the Z2 direction so that a bottom surface of the liquid storage chamber RS is formed by closing the opening section 332 of the flow path substrate 33, the relay flow path 338, and the plurality of supply flow paths 334.

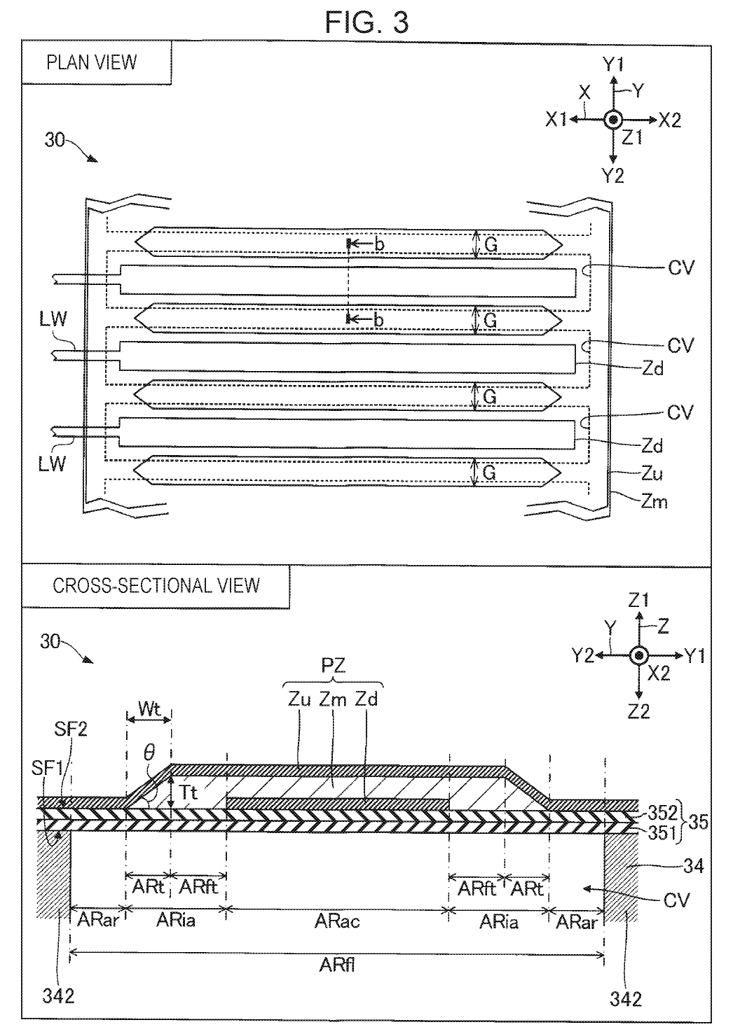

Next, a schematic structure of the piezoelectric device 30 will be described with reference to FIG. 3.

FIG. 3 is an explanatory diagram for explaining a schematic structure of the piezoelectric device 30. The upper part of FIG. 3 is a plan view of the plurality of piezoelectric elements PZ, and the lower part of FIG. 3 is a cross-sectional view taken along line b-b in the plan view. In the plan view of FIG. 3, the peripheral edge of the element located on the back side of any one element is also illustrated by a solid line for convenience. In addition, in the cross-sectional view of FIG. 3, the cross section of the piezoelectric device 30 in a state in which the diaphragm 35 is not deflected is illustrated in order to facilitate the description.

As illustrated in the cross-sectional view of FIG. 3, the piezoelectric element PZ is configured, in outline, by stacking the lower electrode Zd, the piezoelectric layer Zm, and the upper electrode Zu.

The lower electrode Zd is formed at the second surface SF2 of the diaphragm 35. In the present embodiment, the lower electrode Zd is an individual electrode formed for each piezoelectric element PZ. Specifically, as illustrated in the plan view of FIG. 3, the plurality of lower electrodes Zd extending in the direction along the X axis are arranged in the direction along the Y axis at intervals from each other. The drive signal COM for controlling discharge of ink from the nozzle N corresponding to the piezoelectric element PZ is applied to the lower electrode Zd of each piezoelectric element PZ via the wiring substrate 20. For example, the wiring LW to which the drive signal COM is supplied is coupled to the lower electrode Zd of each piezoelectric element PZ. The lower electrode Zd and the wiring LW contain a conductive material such as metal.

The piezoelectric layer Zm is formed at the surface of the lower electrode Zd. The piezoelectric layer Zm is a strip-shaped dielectric film that extends in the direction along the Y axis to be continuous over the plurality of piezoelectric elements PZ. As illustrated in the plan view of FIG. 3, a notch G long in the direction along the X axis is formed in a region corresponding to a gap between the pressure chambers CV adjacent to each other in the piezoelectric layer Zm in plan view. The notch G is a through-hole penetrating the piezoelectric layer Zm. According to the above configuration, since each piezoelectric element PZ is individually deformed for each pressure chamber CV, the propagation of vibration between the piezoelectric elements PZ is suppressed. As a result, it is possible to control the ink discharge characteristics of each nozzle N with high accuracy. The discharge characteristic is, for example, a discharge amount of the ink, a discharge rate of the ink, or a discharge direction of the ink.

The piezoelectric layer Zm is preferably made of crystals preferentially oriented to the (100) plane, for example. For example, the piezoelectric layer Zm is made of a piezoelectric material having a perovskite crystal structure. However, the crystal state of the piezoelectric layer Zm is not limited to a state in which the (100) plane is preferentially oriented. The piezoelectric material is not particularly limited, and examples thereof include lead titanate (PbTiO₃), lead zirconate titanate (PZT: Pb(Zr, Ti)O₃), lead zirconate (PbZrO₃), lead lanthanum titanate ((Pb, La), TiO₃), lead lanthanum zirconate titanate ((Pb, La)(Zr, Ti)O₃), lead zirconate titanate niobate (Pb(Zr, Ti, Nb)O₃), lead zirconate titanate magnesium niobate (Pb(Zr, Ti)(Mg, Nb)O₃), potassium sodium niobate ((K, Na)NbO₃), and the like. Among these, the lead zirconate titanate (PZT) is suitably used as a constituent material of the piezoelectric layer Zm.

The upper electrode Zu is formed at the surface of the piezoelectric layer Zm. In the present embodiment, the upper electrode Zu is a strip-shaped common electrode that extends in the direction along the Y axis to be continuous over the plurality of piezoelectric elements PZ. The upper electrode Zu contains a conductive material such as metal.

The piezoelectric layer Zm is deformed according to the potential difference between the drive signal COM supplied to the lower electrode Zd and the reference potential VBS supplied to the upper electrode Zu. For example, a portion of the piezoelectric layer Zm sandwiched between the lower electrode Zd and the upper electrode Zu is deformed. With this deformation, the piezoelectric element PZ deflects the diaphragm 35. That is, the piezoelectric element PZ vibrates the diaphragm 35 in accordance with the potential difference between the drive signal COM applied to the lower electrode Zd and the reference potential VBS supplied to the upper electrode Zu. The piezoelectric element PZ is individually formed for each pressure chamber CV. Specifically, the plurality of piezoelectric elements PZ elongated in the direction along the X axis are arranged in the direction along the Y axis at intervals from each other. The direction along the X axis corresponds to a direction intersecting the direction along the Y axis in which the plurality of pressure chambers CV are arranged. In the present embodiment, the width of the pressure chamber CV in the direction along the Y axis is larger than the width of the piezoelectric element PZ in the direction along the Y axis.

Here, in the piezoelectric device 30, in plan view, a region in which the pressure chamber CV and the diaphragm 35 overlap is a flexible region ARfl that is deformed in conjunction with the deformation of the piezoelectric element PZ. For example, elastic strain occurs in the flexible region ARfl. The elastic strain is a strain generated by deforming the structure. In the present embodiment, the flexible region ARfl has an active region ARac, an inactive region ARia, and an arm region ARar.

The active region ARac is a region in which the diaphragm 35, the lower electrode Zd, the piezoelectric layer Zm, and the upper electrode Zu overlap in plan view, and is a region that is deformed according to a potential difference between the lower electrode Zd and the upper electrode Zu. In the following, a portion of the piezoelectric layer Zm corresponding to the active region ARac is also referred to as the active region ARac of the piezoelectric layer Zm. The active region ARac of the piezoelectric layer Zm, that is, the portion of the piezoelectric layer Zm sandwiched between the lower electrode Zd and the upper electrode Zu is a portion where piezoelectric strain according to the potential difference between the lower electrode Zd and the upper electrode Zu is generated. Therefore, in the active region ARac of the piezoelectric layer Zm, the piezoelectric strain and elastic strain are generated. Although details will be described with reference to FIG. 4, in the present embodiment, the displacement efficiency of the piezoelectric layer Zm is improved by generating the elastic strain so as not to hinder the displacement of the piezoelectric layer Zm due to the piezoelectric strain.

In addition, the inactive region ARia is a region in which the diaphragm 35, the piezoelectric layer Zm, and one of the lower electrode Zd and the upper electrode Zu overlap, and the diaphragm 35, the piezoelectric layer Zm, and the other of the lower electrode Zd and the upper electrode Zu do not overlap in plan view. In the present embodiment, in the inactive region ARia, the diaphragm 35, the piezoelectric layer Zm, and the upper electrode Zu overlap, and the diaphragm 35, the piezoelectric layer Zm, and the lower electrode Zd do not overlap in plan view. Therefore, the piezoelectric strain corresponding to the potential difference between the lower electrode Zd and the upper electrode Zu is basically not generated in the piezoelectric layer Zm in the inactive region ARia. Therefore, the piezoelectric layer Zm in the inactive region ARia is displaced in accordance with the elastic strain.

In the present embodiment, the piezoelectric layer Zm in the inactive region ARia includes a tapered section ARt that has a tapered shape in which the film thickness decreases toward the arm region ARar in the direction along the Y axis, and a planar portion ARft that has a substantially constant thickness. The planar portion ARft corresponds to a region of the inactive region ARia that does not overlap the tapered section ARt in plan view. In the present embodiment, the length of the width of the inactive region ARia along the Y axis can be secured by providing the planar portion ARft.

A ratio "Tt/Wt" of the maximum thickness Tt of the tapered section ARt in the direction along the Z axis to the width Wt of the tapered section ARt in the direction along the Y axis is preferably 0.36 or more and 0.84 or less. Therefore, for example, when the surface of the tapered section ARt is uniformly inclined, an angle θ formed by the surface of the tapered section ARt and the second surface SF2 of the diaphragm 35 is preferably 20 degrees or more and 40 degrees or less. For example, in an aspect in which the angle θ formed by the surface of the tapered section ARt and the second surface SF2 of the diaphragm 35 is less than 20 degrees, when the thickness of the piezoelectric layer Zm is increased, it is necessary to increase the width of the pressure chamber CV in the direction along the Y axis. Therefore, the piezoelectric device 30 and the liquid discharge head 3 are increased in size. In addition, for example, in an aspect in which the angle θ formed by the surface of the tapered section ARt and the second surface SF2 of the diaphragm 35 is greater than 40 degrees, the continuity of the stress generated by the vibration is deteriorated. In this case, since the stress changes rapidly, a crack or the like is likely to occur in a portion where the film thickness is reduced in the vicinity of the boundary between the inactive region ARia and the arm region ARar. For example, there is a concern that the diaphragm 35 may be broken. In the present embodiment, the ratio "Tt/Wt" of the maximum thickness Tt to the width Wt of the tapered section ARt is set to 0.36 or more and 0.84 or less, so that it is possible to suppress the occurrence of cracks and the like and the increase in size of the piezoelectric device 30 and the like.

The arm region ARar is a region in which the pressure chamber CV, the diaphragm 35, and one of the lower electrode Zd and the upper electrode Zu overlap, and the pressure chamber CV, the diaphragm 35, the other of the lower electrode Zd and the upper electrode Zu, and the piezoelectric layer Zm do not overlap in plan view. In the present embodiment, in the arm region ARar, in plan view, the pressure chamber CV, the diaphragm 35, and the upper electrode Zu overlap, and the pressure chamber CV, the diaphragm 35, the lower electrode Zd, and the piezoelectric layer Zm do not overlap. That is, the arm region ARar is a region in the flexible region ARfl in which the piezoelectric layer Zm is not provided. Therefore, the piezoelectric strain is not generated in the arm region ARar. The arm region ARar is displaced in response to the elastic strain. The arm region ARar corresponds to an arm-shaped portion that elastically supports the inactive region ARia. In the present embodiment, since the arm region ARar is provided, the diaphragm 35 can be easily deflected.

In the present embodiment, the upper electrode Zu is provided over the flexible region ARfl and the region in which the pressure chamber substrate 34 and the diaphragm 35 overlap in plan view in the direction along the Y axis, and the piezoelectric layer Zm is covered with the upper electrode Zu in the inactive region ARia. Therefore, it is possible to suppress the piezoelectric layer Zm from floating or peeling off. Further, in the present embodiment, since the end portion of the piezoelectric layer Zm is covered with the upper electrode Zu, it is possible to alleviate the stress applied to the end portion of the piezoelectric layer Zm.

The configuration of the piezoelectric device 30 is not limited to the example illustrated in FIG. 3. For example, the piezoelectric layer Zm in the inactive region ARia may have only the tapered section ARt without the planar portion ARft. In addition, for example, the arm region ARar may not be provided in the direction along the Y axis.

In addition, in the cross-sectional view of FIG. 3, the state in which the diaphragm 35 is not deflected is illustrated in order to facilitate the description, but in the present embodiment, the diaphragm 35 is deflected even in a state in which the piezoelectric element PZ is not driven.

Next, the deflection of the diaphragm 35 will be described with reference to FIG. 4.

FIG. 4 is an explanatory diagram for explaining the deflection of the diaphragm 35. In FIG. 4, in order to make the drawing easy to see, the upper electrode Zu and the lower electrode Zd are not illustrated, and the inactive region ARia among the active region ARac, the inactive region ARia, and the arm region ARar of the flexible region ARfl is illustrated with a mesh. In addition, in "non-driving time" and "driving time 1" in FIG. 4, the descriptions of the reference sign of the flexible region ARfl and the reference sign of the inactive region ARia and the arm region ARar in the Y direction are omitted in order to make the drawing easy to see. In addition, in FIG. 4, an example of the waveform of the drive signal COM is illustrated in a bracket of the "driving time 1" in FIG. 4. The drive signal COM includes a discharge pulse PL in which the potential returns from the intermediate potential Vc to the intermediate potential Vc via the potential Vl and the potential Vh. The potential Vl is a potential lower than the intermediate potential Vc and is the minimum potential of the discharge pulse PL. The potential Vh is a potential higher than the intermediate potential Vc and is the maximum potential of the discharge pulse PL. That is, the intermediate potential Vc is a potential between the potential Vl and the potential Vh. The discharge pulse PL is not limited to the example illustrated in FIG. 4. For example, the discharge pulse PL may be a pulse in which the potential returns from the intermediate potential Vc to the intermediate potential Vc via the potential Vl.

The "non-driving time" of FIG. 4 schematically illustrates a state of the piezoelectric device 30 viewed from the X2 direction when the piezoelectric element PZ is not driven. The state in which the piezoelectric element PZ is not driven is, for example, a state in which the potential difference between the upper electrode Zu and the lower electrode Zd is maintained at 0 V. In the "non-driving time" in FIG. 4, a case where the reference potential VBS is supplied to the upper electrode Zu and the lower electrode Zd is assumed, but the potential of the upper electrode Zu and the lower electrode Zd is not limited to the reference potential VBS when the potential difference between the upper electrode Zu and the lower electrode Zd is 0 V. For example, a state in which the potentials of the upper electrode Zu and the lower electrode Zd are maintained at the ground potential also corresponds to the state in which the piezoelectric element PZ is not driven.

The "driving time 1" and "driving time 2" in FIG. 4 schematically illustrate the state of the piezoelectric device 30 when viewed from the X2 direction when the piezoelectric element PZ is driven. The state in which the piezoelectric element PZ is driven is, for example, a state in which the potential is supplied to the upper electrode Zu and the lower electrode Zd so that a potential difference is generated between the upper electrode Zu and the lower electrode Zd. For example, the "driving time 1" in FIG. 4 illustrates the state of the piezoelectric device 30 when the reference potential VBS is supplied to the upper electrode Zu and the intermediate potential Vc is supplied to the lower electrode Zd. Further, for example, the "driving time 2" in FIG. 4 illustrates the state of the piezoelectric device 30 when the reference potential VBS is supplied to the upper electrode Zu and the potential Vh is supplied to the lower electrode Zd.

In the following, there may be a case where the state of the piezoelectric device 30 is described with reference to the potential supplied to the lower electrode Zd. For example, the piezoelectric device 30 in which the reference potential VBS is supplied to the upper electrode Zu and the intermediate potential Vc is supplied to the lower electrode Zd may be referred to as the piezoelectric device 30 to which the intermediate potential Vc is supplied. Similarly, the piezoelectric device 30 in which the reference potential VBS is supplied to the upper electrode Zu and the potential Vh is supplied to the lower electrode Zd may be referred to as the piezoelectric device 30 in which the potential Vh is supplied.

In addition, in the following, the difference in the direction along the Z axis between the position of the diaphragm 35 and the upper surface SFu of the partition wall 342 of the pressure chamber substrate 34 is also referred to as a deflection amount DF of the diaphragm 35. For example, a deflection amount DF1 indicates the deflection amount DF of the diaphragm 35 when the potential difference between the upper electrode Zu and the lower electrode Zd is 0 V. In addition, a deflection amount DF2 indicates the deflection amount DF of the diaphragm 35 in the piezoelectric device 30 to which the intermediate potential Vc is supplied, and a deflection amount DF3 indicates the deflection amount DF of the diaphragm 35 in the piezoelectric device 30 to which the potential Vh is supplied. The deflection amount DF2 is larger than the deflection amount DF1, and the deflection amount DF3 is larger than the deflection amount DF2. The upper surface SFu of the partition wall 342 corresponds to the interface between the pressure chamber substrate 34 and the diaphragm 35.

As illustrated in "non-driving time" in FIG. 4, in the present embodiment, a case where the diaphragm 35 is deflected in the Z2 direction in a state in which the piezoelectric element PZ is not driven is assumed. That is, the diaphragm 35 is deflected toward the pressure chamber CV in a state in which the piezoelectric element PZ is not driven. The shape of the deflection of the diaphragm 35 when viewed from the X2 direction includes a curve having a curvature radius Rac in which a curvature center is located in the Z1 direction with respect to the diaphragm 35 and a curve having a curvature radius Rar in which a curvature center is located in the Z2 direction with respect to the diaphragm 35. That is, the shape of the deflection of the diaphragm 35 is a curve having inflection points PI1 and PI2 in which the curvature center is inverted from the Z1 direction to the Z2 direction with respect to the diaphragm 35. For example, the shape of the deflection of the diaphragm 35 in the active region ARac is a curve in which the curvature center is located in the Z1 direction with respect to the diaphragm 35, and the shape of the deflection of the diaphragm 35 in the arm region ARar is a curve in which the curvature center is located in the Z2 direction with respect to the diaphragm 35. In the following, the inflection points PI1 and PI2 may be collectively referred to as an inflection point PI, and the curvature radii Rac and Rar may be collectively referred to as a curvature radius R.

In the example illustrated in FIG. 4, the inflection point PI of the deflection of the diaphragm 35 in a state in which the piezoelectric element PZ is not driven is located in the inactive region ARia in the direction along the Y axis. For example, in the region between the inflection point PI1 and the inflection point PI2, a force Fi1 and a force Fi2 in the direction between the direction toward the center between the inflection point PI1 and the inflection point PI2 and the Z2 direction in the direction along the Y axis are generated by elastic strain. The directions of the force Fi1 and the force Fi2 are the same as or substantially the same as the direction in which the piezoelectric layer Zm contracts. Therefore, in the present embodiment in which the active region ARac is located between the inflection point PI1 and the inflection point PI2, the force Fi1 and the force Fi2 due to the elastic strain do not hinder the displacement of the piezoelectric layer Zm due to the piezoelectric strain. For example, the directions of the force Fi1 and the force Fi2 are the same as or substantially the same as the directions of the forces Fp1 and Fp2 due to the piezoelectric strain illustrated in "driving time 1" and "driving time 2" in FIG. 4. In the following, the force Fi1 and the force Fi2 may be collectively referred to as a force Fi, and the force Fp1 and the force Fp2 may be collectively referred to as a force Fp.

In addition, in the region between the inflection point PI1 and the partition wall 342, a force Fo1 is generated in the direction in which the piezoelectric layer Zm is extended due to the elastic strain. Similarly, in the region between the inflection point PI2 and the partition wall 342, a force Fo2 is generated in the direction in which the piezoelectric layer Zm is extended due to the elastic strain. That is, the directions of the force Fo1 and the force Fo2 generated by the elastic strain are directions opposite to the direction in which the piezoelectric layer Zm contracts. In the following, the force Fo1 and the force Fo2 may be collectively referred to as a force Fo.

In addition, in the shape of the deflection of the diaphragm 35, the curvature radius Rac of a curve between the inflection point PI1 and the inflection point PI2 is preferably larger than the curvature radius Rar of a curve between the inflection point PI1 and the partition wall 342 and the curvature radius Rar of a curve between the inflection point PI2 and the partition wall 342. That is, it is preferable that the curvature radius Rac in the active region ARac is larger than the curvature radius Rar in the arm region ARar. In the present embodiment, the curvature radius Rac in the active region ARac is larger than the curvature radius Rar in the arm region ARar. Therefore, in the present embodiment, the displacement amount of the active region ARac can be secured.

The method of calculating the curvature radius R is not particularly limited, and a known method can be adopted. For example, in the shape of the deflection of the diaphragm 35, a first center point, which is the central point on a curve, may be obtained, and the curvature radius R may be calculated based on the positional coordinates of three points such as a first point and a second point located on both sides separated by a predetermined distance from the first center point, and the first center point. Specifically, the curvature radius R may be calculated using the Pythagoras' theorem for a right triangle whose vertices are three points such as the second center point, which is the center point of the line connecting the first point and the second point, the first point, and the curvature center. In this case, the distance between the curvature center and the first point corresponds to the curvature radius R, and the distance between the curvature center and the second center point corresponds to the distance obtained by subtracting the distance between the first center point and the second center point from the curvature radius R.

Further, as illustrated in the "driving time 1" in FIG. 4, the diaphragm 35 of the piezoelectric device 30 to which the intermediate potential Vc is supplied is also deflected toward the pressure chamber CV. The inflection point PI of the deflection of the diaphragm 35 in the piezoelectric device 30 to which the intermediate potential Vc is supplied is also located in the inactive region ARia in the direction along the Y axis.

When the reference potential VBS is supplied to the upper electrode Zu and the intermediate potential Vc is supplied to the lower electrode Zd, piezoelectric strain corresponding to the potential difference between the lower electrode Zd and the upper electrode Zu is generated in the active region ARac of the piezoelectric layer Zm. As a result, the force Fp is generated in the direction in which the piezoelectric layer Zm contracts. The force Fp indicates a force in the direction in which the piezoelectric layer Zm contracts due to piezoelectric strain, and corresponds to a set of forces due to piezoelectric strain. In addition, since the inflection point PI is located in the flexible region ARfl other than the active region ARac, the active region ARac is located between the inflection points PI. Therefore, the force Fi due to the elastic strain is generated in the active region ARac, but the force Fo due to the elastic strain is not generated. That is, in the piezoelectric device 30 to which the intermediate potential Vc is supplied, the force Fi due to the elastic strain and the force Fp due to the piezoelectric strain are generated in the active region ARac. Since the direction of the force Fi due to the elastic strain is the same as or substantially the same as the direction of the force Fp due to the piezoelectric strain, the force Fi does not hinder the displacement of the piezoelectric layer Zm due to the piezoelectric strain. Therefore, in the present embodiment, the force Fp due to the piezoelectric strain can be efficiently converted into the displacement of the piezoelectric layer Zm in the active region ARac. In the flexible region ARfl, since the piezoelectric strain does not occur in the inactive region ARia and the arm region ARar, the inactive region ARia and the arm region ARar are displaced according to the force Fi or the force Fo due to the elastic strain.

Here, for example, a comparative example where the inflection point PI is located in the active region ARac is considered. In the comparative example, in the active region ARac, the force Fi due to elastic strain and the force Fp due to piezoelectric strain are generated in a region between the inflection point PI1 and the inflection point PI2, and the force Fo due to elastic strain and the force Fp due to piezoelectric strain are generated in a region other than the region between the inflection point PI1 and the inflection point PI2. That is, the force Fp and the force Fo in the direction opposite to the force Fp are generated in the region between the end portion of the active region ARac in the Y1 direction and the inflection point PI1 and the region between the end portion of the active region ARac in the Y2 direction and the inflection point PI2. Therefore, in the comparative example, the displacement of a portion of the piezoelectric layer Zm due to the piezoelectric strain is suppressed by the force Fo due to the elastic strain. As a result, in the comparative example, the displacement efficiency of the piezoelectric layer Zm in the active region ARac is reduced. In addition, when the inflection point PI is located in the active region ARac, the operation of expansion and contraction in the piezoelectric layer Zm becomes discontinuous at the inflection point PI, and thus the risk of breaking the piezoelectric layer Zm is also increased. Meanwhile, in the present embodiment, since the inflection point PI is located in the inactive region ARia, it is possible to suppress the decrease in the displacement efficiency of the piezoelectric layer Zm in the active region ARac and the increase in the risk of breaking the piezoelectric layer Zm.

Further, as illustrated in the "driving time 2" of FIG. 4, the diaphragm 35 of the piezoelectric device 30 to which the potential Vh is supplied is also deflected toward the pressure chamber CV. The inflection point PI of the deflection of the diaphragm 35 in the piezoelectric device 30 to which the potential Vh is supplied is also located in the inactive region ARia in the direction along the Y axis.

In the present embodiment, it is assumed that the diaphragm 35 is most deflected toward the pressure chamber CV when the reference potential VBS is supplied to the upper electrode Zu and the potential Vh, which is the highest potential of the discharge pulse PL, is supplied to the lower electrode Zd. Therefore, the deflection amount DF3 of the diaphragm 35 in the piezoelectric device 30 to which the potential Vh is supplied corresponds to the deflection amount DF of the diaphragm 35 in the state in which the piezoelectric element PZ is driven and the diaphragm 35 is most deflected toward the pressure chamber CV. The condition under which the diaphragm 35 is most deflected toward the pressure chamber CV is not limited to a case where the reference potential VBS is supplied to the upper electrode Zu and the potential Vh is supplied to the lower electrode Zd. In the present embodiment, since the piezoelectric element PZ is driven and the inflection point PI of the deflection of the diaphragm 35 in the state of the maximum deflection toward the pressure chamber CV is also located in the inactive region ARia, the displacement efficiency of the piezoelectric layer Zm in the active region ARac can be improved.

As described above, in the present embodiment, the inflection point PI is located in the inactive region ARia even when the piezoelectric element PZ is driven. Therefore, in the present embodiment, it is possible to suppress the decrease in the displacement efficiency of the piezoelectric layer Zm in the active region ARac and the increase in the risk of the piezoelectric device 30 being destroyed.

In FIG. 4, a case where the inflection point PI of the deflection of the diaphragm 35 is located in the inactive region ARia is illustrated, but the inflection point PI may be located in the arm region ARar in the direction along the Y axis. That is, the inflection point PI of the deflection of the diaphragm 35 may be located in the flexible region ARfl other than the active region ARac in the direction along the Y axis in either the state in which the piezoelectric element PZ is not driven or the state in which the piezoelectric element PZ is driven. However, from the viewpoint of avoiding the concentration of stress in the arm region ARar in which the piezoelectric layer Zm is not formed and the film thickness is thin, it is preferable that the inflection point PI of the deflection of the diaphragm 35 is located in the inactive region ARia. In addition, the inflection point PI of the deflection of the diaphragm 35 is more preferably located in the vicinity of the center of the inactive region ARia from the following viewpoint. For example, from the viewpoint of suppressing the decrease in the displacement efficiency of the piezoelectric layer Zm and suppressing the decrease in the reliability of the piezoelectric layer Zm, the inflection point PI is preferably a position away from the boundary between the inactive region ARia and the active region ARac. In addition, from the viewpoint of suppressing the occurrence of cracks in the arm region ARar, the inflection point PI is preferably a position away from the boundary between the inactive region ARia and the arm region ARar in order to avoid concentration of stress on the arm region ARar having a small film thickness. Therefore, when the inflection point PI of the deflection of the diaphragm 35 is located in the inactive region ARia, it is more preferable that the inflection point PI is located in the vicinity of the center of the inactive region ARia.

In addition, when the piezoelectric layer Zm in the inactive region ARia includes the tapered section ARt and the planar portion ARft, the inflection point PI of the deflection of the diaphragm 35 is preferably located in the planar portion ARft of the piezoelectric layer Zm in the inactive region ARia. For example, since the tapered section ARt is generated by removing the piezoelectric layer Zm by etching, the shape and grain boundaries of the piezoelectric layer Zm tend to be unstable. Therefore, when the inflection point PI of the deflection of the diaphragm 35 is located in the planar portion ARft of the piezoelectric layer Zm in the inactive region ARia, it is possible to stably obtain an effect of suppressing a decrease in the displacement efficiency of the piezoelectric layer Zm in the active region ARac and an increase in the risk of the piezoelectric layer Zm being destroyed. Further, in the present embodiment, since the planar portion ARft is provided, the length of the width of the inactive region ARia along the Y axis can be secured. As a result, in the present embodiment, for example, even when an error occurs in manufacturing, the inflection point PI of the deflection of the diaphragm 35 can be reliably located in the inactive region ARia.

In the present embodiment, since the diaphragm 35 is deflected in the Z2 direction in a state in which the piezoelectric element PZ is not driven, the piezoelectric element PZ is driven such that the diaphragm 35 is not displaced in the direction away from the upper surface SFu of the partition wall 342 in the Z1 direction. That is, in the present embodiment, the diaphragm 35 is not displaced in the Z1 direction in a direction away from the upper surface SFu of the partition wall 342 when the piezoelectric element PZ is driven. For example, in an aspect in which the diaphragm 35 is displaced to be convex in the Z1 direction, the curvature center of the curve indicating the shape of the deflection of the diaphragm 35 in the active region ARac may be located in the Z2 direction with respect to the diaphragm 35. That is, in the aspect in which the diaphragm 35 is displaced to be convex in the Z1 direction, the positional relationship between the curvature center and the diaphragm 35 may be reversed from the initial state. In this case, damage is accumulated at the inflection point PI of the deflection of the diaphragm 35 and the like, and cracks may occur in the diaphragm 35 and the like. Meanwhile, in the present embodiment, since the diaphragm 35 is not displaced to be convex in the Z1 direction, it is possible to suppress the occurrence of cracks in the diaphragm 35 and the like.

The inventor confirmed by simulation that when the inflection point PI of the deflection of the diaphragm 35 in a state in which the piezoelectric element PZ is not driven is located in the inactive region ARia, the inflection point PI of the deflection of the diaphragm 35 is located in the inactive region ARia even in a state in which the piezoelectric element PZ is driven.

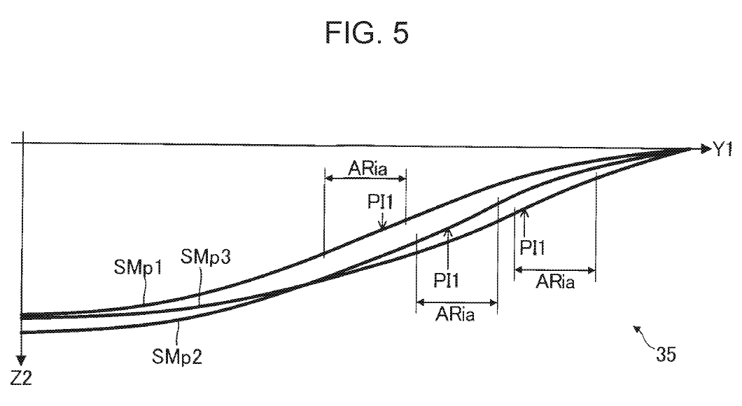

FIG. 5 is a diagram illustrating a simulation result of the deflection of the diaphragm 35. In FIG. 5, a simulation result of the shape of the diaphragm 35 from the center of the width along the Y axis direction of the flexible region ARfl to the end portion in the Y1 direction is illustrated. Specifically, a simulation result of the shape of the diaphragm 35 on line b-b in FIG. 3 when 25 V is applied between the lower electrode Zd and the upper electrode Zu is illustrated.

FIG. 5 illustrates the results of the simulation performed on three configuration patterns in which the ratio of the width of the upper surface of the piezoelectric layer Zm to the width of the predetermined pressure chamber CV is changed. In the following, the ratio of the width of the piezoelectric layer Zm to the width of the predetermined pressure chamber CV is also referred to as a width ratio of the piezoelectric layer Zm. A configuration pattern SMp1 of FIG. 5 illustrates a simulation result when the width ratio of the piezoelectric layer Zm is substantially 57%, a configuration pattern SMp2 illustrates a simulation result when the width ratio of the piezoelectric layer Zm is substantially 71%, and a configuration pattern SMp3 illustrates a simulation result when the width ratio of the piezoelectric layer Zm is substantially 86%. In any of the three configuration patterns, it was confirmed that the inflection point PI1 is located in the inactive region ARia.

For example, in the configuration pattern SMp1, the inflection point PI is located between the boundary between the inactive region ARia and the arm region ARar and the center of the inactive region ARia. In addition, for example, in the configuration pattern SMp2, the inflection point PI is located near the center of the inactive region ARia. In the configuration pattern SMp3, the inflection point PI is located between the boundary between the inactive region ARia and the active region ARac and the center of the inactive region ARia. From this simulation result, for example, when the width ratio of the piezoelectric layer Zm increases, it is estimated that the position of the inflection point PI in the inactive region ARia approaches the boundary between the inactive region ARia and the active region ARac. For example, when the width ratio of the piezoelectric layer Zm is 70% to 75%, the inflection point PI is located in the vicinity of the center of the inactive region ARia. For example, from the viewpoint of suppressing the decrease in the displacement efficiency of the piezoelectric layer Zm and suppressing the decrease in the reliability of the piezoelectric layer Zm, it is preferable that the width ratio of the piezoelectric layer Zm is 75% or less because the inflection point PI is preferably present at a position away from the boundary between the inactive region ARia and the active region ARac. In addition, from the viewpoint of suppressing the occurrence of cracks in the arm region ARar, it is preferable that the width ratio of the piezoelectric layer Zm is 70% or more because the fact that the inflection point PI is present at a position away from the boundary between the inactive region ARia and the arm region ARar is preferable. That is, the ratio of the width of the piezoelectric layer Zm to the width of the pressure chamber CV is preferably 70% or more and 75% or less.

In the above description, it is illustrated that the inflection point PI can be located in the inactive region ARia by adjusting the width ratio of the piezoelectric layer Zm, but the element to be adjusted is not limited to the width ratio of the piezoelectric layer Zm. For example, the inflection point PI may be located in the inactive region ARia by adjusting the film thickness of the piezoelectric element PZ, the mass of the material, and the like.

In the above description, in the present embodiment, the piezoelectric device 30 includes the diaphragm 35 that is coupled to the pressure chamber substrate 34 and partitions a part of the pressure chamber CV together with the pressure chamber substrate 34, and the piezoelectric element PZ in which the lower electrode Zd, the piezoelectric layer Zm, and the upper electrode Zu are stacked in this order along the stacking direction on the side opposite to the pressure chamber CV of the diaphragm 35. The diaphragm 35 vibrates in response to the drive of the piezoelectric element PZ. When the region in which the pressure chamber CV and the diaphragm 35 overlap when viewed in the stacking direction is defined as the flexible region ARfl in the width direction intersecting the stacking direction, the flexible region ARfl includes the active region ARac in which the diaphragm 35, the lower electrode Zd, the piezoelectric layer Zm, and the upper electrode Zu overlap when viewed in the stacking direction. The inflection point PI of the deflection of the diaphragm 35 in a state in which the piezoelectric element PZ is not driven is located in the flexible region ARfl other than the active region ARac in the width direction.

As described above, in the present embodiment, the inflection point PI of the deflection of the diaphragm 35 in the state in which the piezoelectric element PZ is not driven is located in the flexible region ARfl other than the active region ARac. As a result, in the present embodiment, it is possible to suppress the displacement of the piezoelectric layer Zm due to the piezoelectric strain generated in the piezoelectric layer Zm when the piezoelectric element PZ is driven from being hindered by the forces Fi and Fo due to the elastic strain generated by the diaphragm 35 or the like being deformed. As a result, in the present embodiment, it is possible to suppress the decrease in the displacement efficiency of the piezoelectric layer Zm.

In addition, in the present embodiment, the flexible region ARfl includes the inactive region ARia in which the diaphragm 35, the piezoelectric layer Zm, and one of the lower electrode Zd and the upper electrode Zu overlap, and the diaphragm 35, the piezoelectric layer Zm, and the other of the lower electrode Zd and the upper electrode Zu do not overlap when viewed in the stacking direction. The diaphragm 35 is deflected toward the pressure chamber CV in a state in which the piezoelectric element PZ is not driven. The inflection point PI of the deflection of the diaphragm 35 in a state in which the piezoelectric element PZ is not driven may be located in the inactive region ARia in the width direction. Also in the present aspect, since the inflection point PI of the deflection of the diaphragm 35 is not located in the active region ARac, it is possible to suppress the displacement efficiency of the piezoelectric layer Zm from being lowered.

In addition, in the present embodiment, the flexible region ARfl may include the inactive region ARia in which the diaphragm 35, the piezoelectric layer Zm, and one of the lower electrode Zd and the upper electrode Zu overlap, and the diaphragm 35, the piezoelectric layer Zm, and the other of the lower electrode Zd and the upper electrode Zu do not overlap when viewed in the stacking direction, and the arm region ARar in which the pressure chamber CV, the diaphragm 35, and one of the lower electrode Zd and the upper electrode Zu overlaps, and the pressure chamber CV, the diaphragm 35, the other of the lower electrode Zd and the upper electrode Zu, and the piezoelectric layer Zm do not overlap when viewed in the stacking direction. The inflection point PI of the deflection of the diaphragm 35 in a state in which the piezoelectric element PZ is not driven may be located in the inactive region ARia in the width direction. Also in the present aspect, since the inflection point PI of the deflection of the diaphragm 35 is not located in the active region ARac, it is possible to suppress the displacement efficiency of the piezoelectric layer Zm from being lowered. Further, in the present mode, since the arm region ARar is provided, the diaphragm 35 and the piezoelectric layer Zm are easily deflected. Therefore, in the present mode, the displacement amount of the piezoelectric layer Zm can be increased. Further, in the present aspect, since the inflection point PI of the deflection of the diaphragm 35 is located in the inactive region ARia, it is possible to suppress the occurrence of cracks in the arm region ARar having a thin film thickness, without forming the piezoelectric layer Zm. That is, in the present aspect, it is possible to suppress the risk of the piezoelectric layer Zm being destroyed.

In the present embodiment, the piezoelectric layer Zm in the inactive region ARia may have the tapered section ARt that has a tapered shape in which the film thickness is reduced toward the arm region ARar in the width direction. The inflection point PI of the deflection of the diaphragm 35 in a state in which the piezoelectric element PZ is not driven may be located in the region of the inactive region ARia that does not overlap the tapered section ARt when viewed in the stacking direction in the width direction. That is, in the present embodiment, the inactive region ARia includes a region that overlaps the tapered section ARt when viewed in the stacking direction and a region that does not overlap the tapered section ARt when viewed in the stacking direction. As described above, in the present embodiment, the inactive region ARia includes a region that does not overlap the tapered section ARt when viewed in the stacking direction, and thus a length along the width direction of the inactive region ARia can be secured. As a result, in the present embodiment, even when an error occurs in manufacturing, the inflection point PI of the deflection of the diaphragm 35 can be reliably located in the inactive region ARia. In addition, in the inactive region ARia, the region that does not overlap the tapered section ARt when viewed in the stacking direction is a region corresponding to the planar portion ARft of the piezoelectric layer Zm. In the planar portion ARft of the piezoelectric layer Zm, the shape and grain boundary of the piezoelectric layer Zm are more stable than those of the tapered section ARt. In the present aspect, since the inflection point PI of the deflection of the diaphragm 35 is located in the region that does not overlap the tapered section ARt when viewed in the stacking direction, it is possible to stably obtain an effect of suppressing a decrease in the displacement efficiency of the piezoelectric layer Zm and an increase in the risk of the piezoelectric layer Zm being destroyed.

In the present embodiment, the ratio of the maximum thickness Tt of the tapered section ARt in the stacking direction to the width Wt of the tapered section ARt in the width direction may be 0.36 or more and 0.84 or less. In this case, it is possible to suppress the occurrence of cracks and the like and the increase in size of the piezoelectric device 30 and the like.

In the present embodiment, the inflection point PI of the deflection of the diaphragm 35 in the state in which the piezoelectric element PZ is not driven may be located in the arm region ARar in the width direction. Also in the present aspect, since the inflection point PI of the deflection of the diaphragm 35 is not located in the active region ARac, it is possible to suppress the displacement efficiency of the piezoelectric layer Zm from being lowered.

In the present embodiment, the curvature radius Rac in the active region ARac is larger than the curvature radius Rar in the arm region ARar in a state in which the piezoelectric element PZ is not driven. As a result, in the present embodiment, the displacement amount of the active region ARac can be secured.

In the present embodiment, the inflection point PI of the deflection of the diaphragm 35 in the state of being driven by the piezoelectric element PZ and being most deflected toward the pressure chamber CV is located in the flexible region ARfl other than the active region ARac in the width direction. In the present embodiment, even in a state in which the piezoelectric element PZ is driven and the diaphragm 35 is most deflected toward the pressure chamber CV, the inflection point PI of the deflection of the diaphragm 35 is located in the flexible region ARfl other than the active region ARac, and thus the displacement efficiency of the piezoelectric layer Zm can be improved.

In the present embodiment, the inflection point PI of the deflection of the diaphragm 35 in the state of being driven by the piezoelectric element PZ and being most deflected toward the pressure chamber CV may be located in the inactive region ARia in the width direction. Also in the present aspect, since the inflection point PI of the deflection of the diaphragm 35 in the most deflected state toward the pressure chamber CV is not located in the active region ARac, the displacement efficiency of the piezoelectric layer Zm can be improved.

In addition, in the present embodiment, the inflection point PI of the deflection of the diaphragm 35 in a state in which the reference potential VBS is supplied to one of the lower electrode Zd and the upper electrode Zu and the intermediate potential Vc different from the reference potential VBS is supplied to the other of the lower electrode Zd and the upper electrode Zu may be located in the inactive region ARia in the width direction. In the present aspect, even in an intermediate state until the state of the diaphragm 35 becomes the most deflected state from the initial state, the inflection point PI of the deflection of the diaphragm 35 is not located in the active region ARac, and thus the displacement efficiency of the piezoelectric layer Zm can be improved.

In the present embodiment, the diaphragm 35 is not displaced in the direction away from the interface between the pressure chamber substrate 34 and the diaphragm 35 in the direction away from the pressure chamber CV when the piezoelectric element PZ is driven. In the present embodiment, the positional relationship between the curvature center of the curve indicating the deflection of the diaphragm 35 and the diaphragm 35 is prevented from being reversed from the initial state, and thus it is possible to suppress the occurrence of cracks in the diaphragm 35 and the like.

In addition, in the present embodiment, the piezoelectric layer Zm may be made of lead zirconate titanate.

In addition, in the present embodiment, the upper electrode Zu is provided over the flexible region ARfl and the region in which the pressure chamber substrate 34 and the diaphragm 35 overlap when viewed in the stacking direction, in the width direction, and covers the piezoelectric layer Zm in the inactive region ARia. Therefore, in the present embodiment, it is possible to suppress the piezoelectric layer Zm from floating or peeling. Further, in the present embodiment, since the end portion of the piezoelectric layer Zm is covered with the upper electrode Zu, it is possible to alleviate the stress applied to the end portion of the piezoelectric layer Zm.

In the present embodiment, the liquid discharge head 3 includes the above-described piezoelectric device 30, and discharges the liquid by driving the piezoelectric device 30. As a result, in the present embodiment, it is possible to suppress the decrease in the displacement efficiency of the piezoelectric layer Zm included in the piezoelectric device 30 of the liquid discharge head 3.

### 2. Modification Example

Each embodiment above can be variously modified. A specific aspect of the modification will be described below. Two or more aspects selected in any manner from the following examples can be combined with each other as appropriate within a range not inconsistent with each other. In addition, in the modification examples described below, elements having the same effects and functions as those of the embodiment will be given the reference numerals used in the description above, and each detailed description thereof will be omitted as appropriate.

### First Modification Example

In the above-described embodiment, a case where the lower electrode Zd is an individual electrode and the upper electrode Zu is a common electrode is exemplified, but the present disclosure is not limited to such an aspect. For example, the lower electrode Zd may be a common electrode that is continuous over the plurality of piezoelectric elements PZ, and the upper electrode Zu may be an individual electrode that is individual for each piezoelectric element PZ. Specifically, the lower electrode Zd may be provided over the flexible region ARfl and the region in which the pressure chamber substrate 34 and the diaphragm 35 overlap in plan view in the direction along the Y axis.

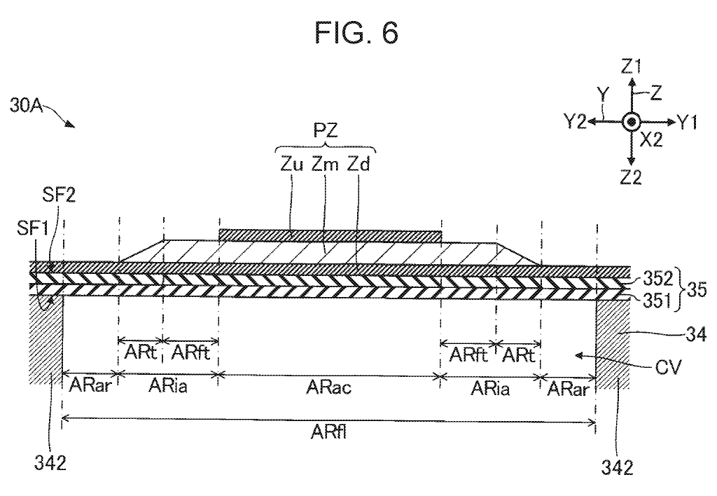

FIG. 6 is a cross-sectional view of a piezoelectric device 30A according to a first modification example. FIG. 6 illustrates a cross section of a portion corresponding to the line b-b in the plan view illustrated in FIG. 3. Further, also in FIG. 6, in order to make the description easy to understand, the cross section of the piezoelectric device 30 in a state in which the diaphragm 35 is not deflected is illustrated in the same manner as the cross-sectional view of FIG. 3. A piezoelectric device 30A illustrated in FIG. 6 is the same as the piezoelectric device 30 illustrated in FIG. 3 except that the lower electrode Zd is a common electrode and the upper electrode Zu is an individual electrode. Further, the liquid discharge head 3 according to the present modification example is the same as the liquid discharge head 3 according to the above-described embodiment, except that the piezoelectric device 30A is provided instead of the piezoelectric device 30 illustrated in FIG. 3. In FIG. 6, the difference between the piezoelectric device 30A and the piezoelectric device 30 will be mainly described.

The lower electrode Zd is formed at the second surface SF2 of the diaphragm 35. In the present modification example, the lower electrode Zd is a strip-shaped common electrode that extends in the direction along the Y axis to be continuous over the plurality of piezoelectric elements PZ. For example, the lower electrode Zd is provided over the flexible region ARfl and the region in which the pressure chamber substrate 34 and the diaphragm 35 overlap in plan view in the direction along the Y axis. The reference potential VBS is supplied to the lower electrode Zd.

The upper electrode Zu is formed at the surface of the piezoelectric layer Zm. In the present modification example, the upper electrode Zu is the individual electrode formed for each piezoelectric element PZ. For example, in the present modification example, the plurality of upper electrodes Zu extending in the direction along the X axis are arranged in the direction along the Y axis at intervals from each other. The drive signal COM is supplied to the upper electrode Zu. In the present modification example, for example, when the potential Vh, which is the highest potential of the discharge pulse PL, is supplied to the upper electrode Zu and the reference potential VBS is supplied to the lower electrode Zd, the diaphragm 35 is most deflected toward the pressure chamber CV.

In addition, in the piezoelectric device 30A, the inactive region ARia is the region in the flexible region ARfl in which the diaphragm 35, the piezoelectric layer Zm, and the lower electrode Zd overlap, and the diaphragm 35, the piezoelectric layer Zm, and the upper electrode Zu do not overlap in plan view. That is, the piezoelectric layer Zm in the inactive region ARia is not covered with the upper electrode Zu. Further, in the piezoelectric device 30A, the piezoelectric layer Zm in the inactive region ARia also includes the tapered section ARt and the planar portion ARft in the direction along the Y axis, as in the piezoelectric device 30. As described above, also in the piezoelectric device 30A, the length of the width of the inactive region ARia along the Y axis can be secured because the planar portion ARft is provided. As a result, even in the piezoelectric device 30A, for example, even when a manufacturing error occurs, the inflection point PI of the deflection of the diaphragm 35 can be reliably located in the inactive region ARia.

As illustrated in FIG. 6, in the piezoelectric device 30A, since the lower electrode Zd is provided over the flexible region ARfl and the region in which the pressure chamber substrate 34 and the diaphragm 35 overlap in plan view, it is possible to alleviate the stress at the interface between the pressure chamber substrate 34 and the diaphragm 35.

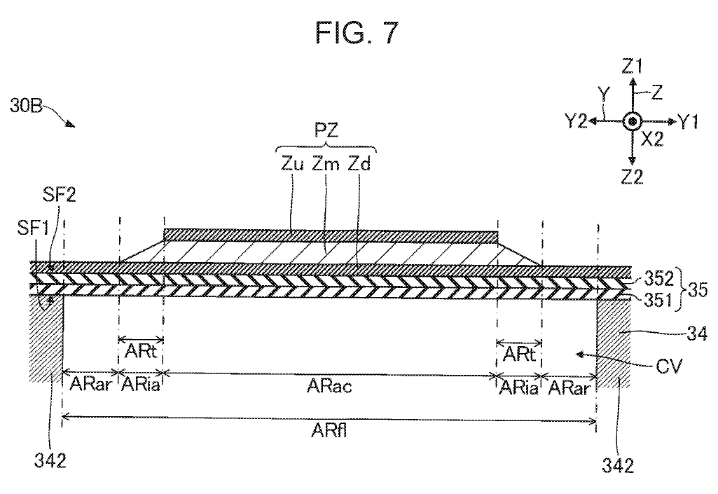

The configuration of the piezoelectric device 30A according to the present modification example is not limited to the example illustrated in FIG. 6. For example, the arm region ARar may not be provided. In addition, for example, as illustrated in FIG. 7, the planar portion ARft of the piezoelectric layer Zm may not be provided in the inactive region ARia.

FIG. 7 is a cross-sectional view of a piezoelectric device 30B according to another example of the first modification example. FIG. 7 illustrates a cross section of a portion corresponding to line b-b in the plan view illustrated in FIG. 3. Further, also in FIG. 7, in order to make the description easy to understand, the cross section of the piezoelectric device 30 in a state in which the diaphragm 35 is not deflected is illustrated in the same manner as the cross-sectional view of FIG. 3. The piezoelectric device 30B illustrated in FIG. 7 is the same as the piezoelectric device 30A illustrated in FIG. 6 except that the planar portion ARft of the piezoelectric layer Zm is not provided in the inactive region ARia. Further, the liquid discharge head 3 according to the present modification example is the same as the liquid discharge head 3 according to the above-described embodiment, except that the piezoelectric device 30B is provided instead of the piezoelectric device 30 illustrated in FIG. 3. In FIG. 7, the difference between the piezoelectric device 30A and the piezoelectric device 30B will be mainly described.

The upper electrode Zu is formed at the surface of a portion of the piezoelectric layer Zm excluding the tapered section ARt. That is, in the piezoelectric device 30B, the piezoelectric layer Zm in the inactive region ARia does not include the planar portion ARft, and includes only the tapered section ARt. Other configurations of the piezoelectric device 30B are the same as those of the piezoelectric device 30A illustrated in FIG. 6.

Also in the present modification example, the inflection point PI of the deflection of the diaphragm 35 is located in the inactive region ARia or the arm region ARar, as in the above-described embodiment. As described above, in the present modification example, the same effect as that of the embodiment described above can be obtained.

### Second Modification Example

In the above-described embodiment and modification example, a case where the diaphragm 35 is deflected toward the pressure chamber CV in a state in which the piezoelectric element PZ is not driven is exemplified, but the present disclosure is not limited to such an aspect. For example, the diaphragm 35 may be deflected in the direction away from the pressure chamber CV, that is, in the Z1 direction, in a state in which the piezoelectric element PZ is not driven. Also in the present modification example, when the potential Vh, which is the highest potential of the discharge pulse PL, is supplied to the individual electrode and the reference potential VBS is supplied to the common electrode, the diaphragm 35 is most deflected toward the pressure chamber CV. In the present modification example, when the piezoelectric element PZ is driven, the diaphragm 35 may be displaced in the direction away from the interface between the pressure chamber substrate 34 and the diaphragm 35 in the direction away from the pressure chamber CV, or may not be displaced in a direction away from the interface. Also in the present modification example, the inflection point PI of the deflection of the diaphragm 35 is located in the inactive region ARia or the arm region ARar, as in the above-described embodiment. As described above, in the present modification example, the same effect as that of the embodiment described above can be obtained.

### Third Modification Example

In the above-described embodiment and modification examples, the case where the piezoelectric device 30 is used for the liquid discharge head 3 is described as an example, but the piezoelectric device 30 may be used for a device other than the liquid discharge head 3. For example, the piezoelectric device 30 may be used for various sensors such as an ultrasonic sensor and a pressure sensor, a piezoelectric pump, and various devices such as a piezoelectric speaker. As described above, in the present modification example, the same effects as those of the embodiment and the modification examples described above can be obtained.

What is claimed is:

1. A piezoelectric device comprising:
a diaphragm that is coupled to a first substrate and partitions a part of a space together with the first substrate; and
a piezoelectric element in which a lower electrode, a piezoelectric layer, and an upper electrode are stacked in this order along a stacking direction on a side opposite to the space of the diaphragm, wherein
the diaphragm vibrates in response to driving of the piezoelectric element,
when a region in which the space and the diaphragm overlap when viewed in the stacking direction is defined as a flexible region in a width direction intersecting the stacking direction, the flexible region includes an active region in which the diaphragm, the lower electrode, the piezoelectric layer, and the upper electrode overlap when viewed in the stacking direction, and
an inflection point of deflection of the diaphragm in a state in which the piezoelectric element is not driven is located in a portion of the flexible region other than the active region in the width direction.

2. The piezoelectric device according to claim 1, wherein
the flexible region includes an inactive region in which, when viewed in the stacking direction,
the diaphragm overlaps the piezoelectric layer and one of the lower electrode and the upper electrode, and
the diaphragm does not overlap the other of the lower electrode and the upper electrode,
the diaphragm is deflected toward the space in a state in which the piezoelectric element is not driven, and
the inflection point of the deflection of the diaphragm in the state in which the piezoelectric element is not driven is located in the inactive region in the width direction.

3. The piezoelectric device according to claim 1, wherein
the flexible region includes
an inactive region in which, when viewed in the stacking direction,
the diaphragm overlaps the piezoelectric layer and one of the lower electrode and the upper electrode, and
the diaphragm does not overlap the other of the lower electrode and the upper electrode, and
an arm region in which, when viewed in the stacking direction,
the diaphragm overlaps the one of the lower electrode and the upper electrode, and
the diaphragm does not overlap the piezoelectric layer and the other of the lower electrode and the upper electrode, and
the inflection point of the deflection of the diaphragm in the state in which the piezoelectric element is not driven is located in the inactive region in the width direction.

4. The piezoelectric device according to claim 3, wherein
the piezoelectric layer in the inactive region has a tapered section that has a tapered shape in which a film thickness becomes thinner toward the arm region in the width direction, and
the inflection point of the deflection of the diaphragm in a state in which the piezoelectric element is not driven is located in a region of the inactive region in the width direction that does not overlap the tapered section when viewed in the stacking direction.

5. The piezoelectric device according to claim 4, wherein
a ratio of a maximum thickness of the tapered section in the stacking direction to a width of the tapered section in the width direction is 0.36 or more and 0.84 or less.

6. The piezoelectric device according to claim 1, wherein
the flexible region includes
an inactive region in which, when viewed in the stacking direction,
the diaphragm overlaps the piezoelectric layer and one of the lower electrode and the upper electrode, and
the diaphragm does not overlap the other of the lower electrode and the upper electrode, and
an arm region in which, when viewed in the stacking direction,
the diaphragm overlaps the one of the lower electrode and the upper electrode, and
the diaphragm does not overlap the piezoelectric layer and the other of the lower electrode and the upper electrode, and
the inflection point of the deflection of the diaphragm in the state in which the piezoelectric element is not driven is located in the arm region in the width direction.

7. The piezoelectric device according to claim 3, wherein
a curvature radius in the active region is larger than a curvature radius in the arm region in the state in which the piezoelectric element is not driven.

8. The piezoelectric device according to claim 2, wherein
the inflection point of the deflection of the diaphragm in a state of being most deflected toward the space when the piezoelectric element is driven is located in a portion of the flexible region other than the active region in the width direction.

9. The piezoelectric device according to claim 3, wherein
the inflection point of the deflection of the diaphragm in a state of being most deflected toward the space when the piezoelectric element is driven is located in the inactive region in the width direction.

10. The piezoelectric device according to claim 9, wherein
the inflection point of the deflection of the diaphragm in a state in which a reference potential is supplied to one of the lower electrode and the upper electrode and an intermediate potential different from the reference potential is supplied to the other of the lower electrode and the upper electrode is located in the inactive region in the width direction.

11. The piezoelectric device according to claim 1, wherein
the diaphragm is not displaced in a direction away from an interface between the first substrate and the diaphragm in a direction away from the space when the piezoelectric element is driven.

12. The piezoelectric device according to claim 1, wherein
the piezoelectric layer is made of lead zirconate titanate.

13. The piezoelectric device according to claim 2, wherein
the upper electrode is provided over the flexible region and a region in which the first substrate and the diaphragm overlap when viewed in the stacking direction, in the width direction, and
the upper electrode covers the piezoelectric layer in the inactive region.

14. The piezoelectric device according to claim 2, wherein
the lower electrode is provided over the flexible region and a region in which the first substrate and the diaphragm overlap when viewed in the stacking direction, in the width direction.

15. A liquid discharge head comprising:
the piezoelectric device according to claim 1, wherein
liquid is discharged by driving the piezoelectric device.

16. A piezoelectric device comprising:
a diaphragm that is coupled to a first substrate and partitions a part of a space together with the first substrate; and
a piezoelectric element in which a lower electrode, a piezoelectric layer, and an upper electrode are stacked in this order along a stacking direction on a side opposite to the space of the diaphragm, wherein
the diaphragm vibrates in response to driving of the piezoelectric element,
when a region in which the space and the diaphragm overlap when viewed in the stacking direction is defined as a flexible region in a width direction intersecting the stacking direction, the flexible region includes an active region in which the diaphragm, the lower electrode, the piezoelectric layer, and the upper electrode overlap when viewed in the stacking direction, and
an inflection point of deflection of the diaphragm in a state of being most deflected toward the space when the piezoelectric element is driven is located in a portion of the flexible region other than the active region in the width direction.

17. The piezoelectric device according to claim 16, wherein
the flexible region includes
an inactive region in which, when viewed in the stacking direction,
the diaphragm overlaps the piezoelectric layer and one of the lower electrode and the upper electrode, and
the diaphragm does not overlap the other of the lower electrode and the upper electrode, and
an arm region in which, when viewed in the stacking direction,
the diaphragm overlaps the one of the lower electrode and the upper electrode, and
the diaphragm does not overlap the piezoelectric layer and the other of the lower electrode and the upper electrode, and
the inflection point of the deflection of the diaphragm in a state of being most deflected toward the space when the piezoelectric element is driven is located in the inactive region in the width direction.
